(19) United States
(12) Patent Application Publication
(10) Pub. No.: US 2009/0098727 A1
(43) Pub. Date: Apr. 16, 2009

(54) Method of Forming Metal Line of Semiconductor Device

(75) Inventors: Seung Hee Hong, Seoul (KR); Cheol Mo Jeong, Icheon-Si (KR); Eun Soo Kim, Incheon-Si (KR)

Correspondence Address: MARSHALL, GERSTEIN & BORUN LLP, 233 SOUTH WACKER DRIVE, 6300 SEARS TOWER, CHICAGO, IL, 60606-6357, US

(73) Assignee: HYNIX SEMICONDUCTOR INC., Icheon-si (KR)

(21) Appl. No.: 12/147,196

(22) Filed: Jun. 26, 2008

(30) Foreign Application Priority Data
Oct. 10, 2007 (KR) 10-2007-0102126

(51) Int. Cl. H01L 21/768

(52) U.S. Cl. 438/627; 257/E21.584

(57) ABSTRACT

Disclosed herein is a method of forming a metal line of a semiconductor device. According to the method, a contact hole is formed in a second insulating layer over a semiconductor substrate. A first barrier metal layer, including a TiN layer, is formed on a surface of the second insulating layer. The first barrier metal layer is formed such that the TiN layer is formed thinner at a bottom of the contact hole than on sidewalls and a top surface of the second insulating layer. A first metal layer is formed on the first barrier metal layer, including on the contact hole. Thermal treatment is carried to gap-fill the contact hole as the first metal layer is reflown and smooth. A second metal layer is formed on the first metal layer. The second metal layer to form an upper metal line.

### CROSS-REFERENCES TO RELATED APPLICATIONS

Priority to Korean patent application number 10-2007-0102126 filed Oct. 10, 2007, the disclosure of which is incorporated by reference in its entirety, is claimed.

### BACKGROUND OF THE INVENTION

1. Field of Invention

The invention relates generally to a method of forming a metal line of a semiconductor device and, more particularly, to a method of forming a metal line that can reduce contact resistance and improve a gap-fill characteristic.

2. Background of Related Technology

A metal line process refers to a process of connecting metallic lines to respective circuits formed in a semiconductor substrate. Typically, the metal line process is performed using metals, such as aluminum (Al), copper (Cu), gold (Au), or tungsten (W). With the high integration of semiconductor devices, the design rule is decreased and a higher program speed is required. Thus, a line formation method employing metals having low resistivity and low-k materials has emerged, instead of the current line formation method employing tungsten (W).

In general, the metal line of a semiconductor device is formed using a damascene scheme. The process of forming a metal line of a semiconductor device employing the damascene scheme is described in short below. First, a pre-metal dielectric layer is deposited on a semiconductor substrate in which structures, such as gates, are formed. A trench is formed and a barrier metal layer made of Ti/TiN is formed on the pre-metal dielectric layer including the trench. A tungsten (W) layer is formed on the barrier metal layer so that the trench is gap-filled. The tungsten (W) layer and the barrier metal layer of the Ti/TiN stacked layer are polished by a chemical mechanical polishing (CMP) process, thus forming a tungsten (W) metal line within the trench.

However, when aluminum (Al) is employed in the damascene scheme, problems, such as dishing and scratch, are generated at the time of the CMP process due to the relative softness of aluminum (Al). This becomes a factor to degrade reliability when forming a metal line. Aluminum (Al) has the Ti/TiN layer deposited thereon. In a subsequent contact formation process, etch is not exactly stopped on aluminum (Al), so contact resistance may increase abnormally. If only TiN is deposited without Ti or if the thickness of Ti is small, Al reacts with N₂ gas when aluminum (Al) and TiN are deposited, thus forming AlN. This results in increased contact resistance.

### BRIEF SUMMARY OF THE INVENTION

The invention is directed towards a method of forming a metal line of a semiconductor device. The method can reduce contact resistance, improve a gap-fill characteristic, and form a low-k metal line on a contact plug, by reducing the area occupied by a barrier metal layer within a contact hole, while minimizing reaction of an aluminum layer, which gap-fills the contact hole, and the barrier metal layer, in a method of forming a metal line in which an aluminum layer is deposited on the barrier metal layer using a chemical vapor deposition (CVD) method.

According to a method of forming a metal line of a semiconductor device in accordance with an embodiment, a lower metal line and a first insulating layer can be formed over the semiconductor substrate. The lower metal line can include aluminum (Al).

The first insulating layer can be formed using materials having etch selectivity different from that of the lower metal line. The first insulating layer can include a silicon oxynitride (SiON) layer. A second insulating layer can be formed on the first insulating layer. A contact hole is formed in a second insulating layer over a semiconductor substrate. When the contact hole is formed, etch is stopped on a top surface of the lower metal line.

A first barrier metal layer, including a TiN layer, can be formed on a surface of the second insulating layer. The first barrier metal layer can be formed such that the TiN layer is formed thinner at a bottom of the contact hole than on sidewalls and a top surface of the second insulating layer. A first metal layer is formed on the first barrier metal layer, including on the contact hole. Thermal treatment is carried out to gap-fill the contact hole as the first metal layer is reflown and smooth. A second metal layer is formed on the first metal layer. The second metal layer can be patterned to form an upper metal line.

The TiN layer is formed using a physical vapor deposition (PVD) method. The TiN layer can have a thickness of about 100 to about 200 angstroms.

The first barrier metal layer can have a stacked structure of a Ti layer, a Ti-rich TiₓN layer (wherein x is an integer greater than 1), and the TiN layer. The Ti layer can have a thickness of about 100 to about 300 angstroms. The Ti-rich TiₓN layer is formed by purging N₂ gas in a last deposition step of the Ti layer and flowing heated Ar gas into a chamber such that a temperature within the chamber and a temperature of the semiconductor substrate are raised, and a top surface of the Ti layer is substituted with the Ti-rich TiₓN layer through reaction.

The first metal layer and the second metal layer each includes aluminum (Al). The first metal layer is formed by a chemical vapor deposition (CVD) method employing methyl pyrrolidine alane (MPA, (CH₃)(CH₂)₄N.AlH₃)) source as a precursor. The first metal layer can have a thickness of about 500 to about 1000 angstroms.

The thermal treatment including raising a temperature of the semiconductor substrate to about 430 to about 450 degrees Celsius. The second metal layer is formed by a PVD method. The PVD method includes performing a cold deposition step, a pre-heat step and a hot deposition step. The second metal layer, an aluminum (Al) layer, can have a thickness of about 2000 to about 3000 angstroms. The temperature of a chamber and the semiconductor substrate is raised through the pre-heat step using heated argon (Ar), and the hot deposition step increases the thickness of the aluminum (Al) layer to about 2000 to about 5000 angstroms.

A second barrier metal layer can be formed on the upper metal line. The second barrier metal layer has a stacked layer of Ti and TiN.

### BRIEF DESCRIPTION OF THE DRAWINGS

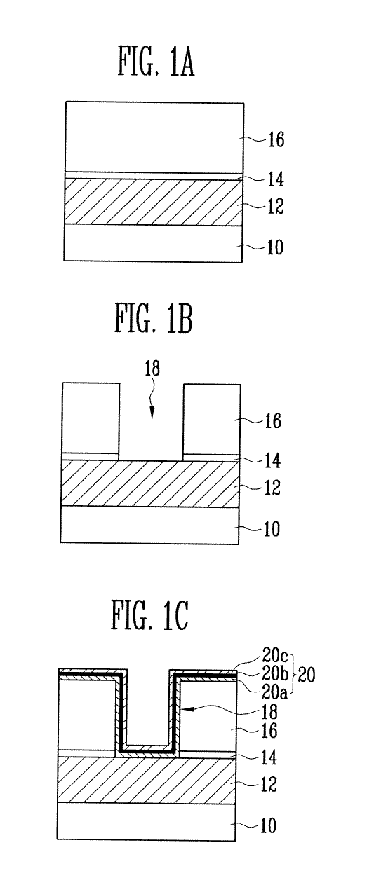

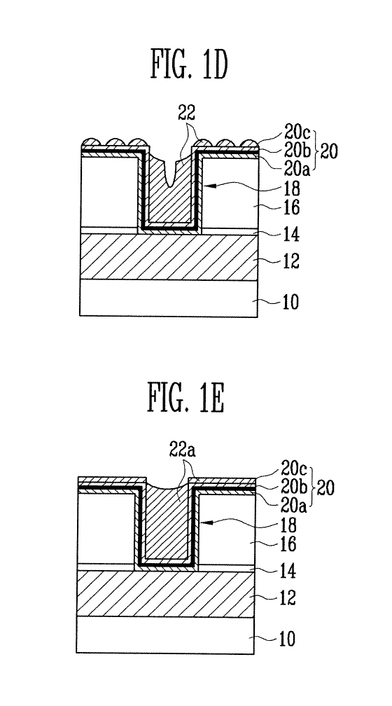

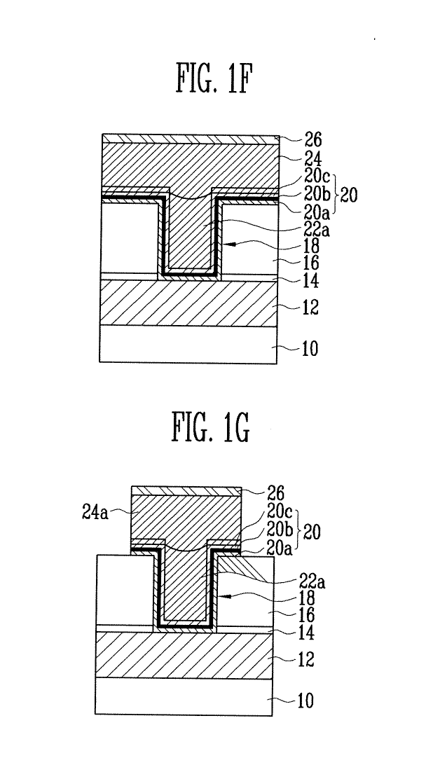

For a more complete understanding of the disclosure, reference should be made to the following detailed description and accompanying drawings, wherein FIGS. 1A to 1G are sectional views illustrating a method of forming a metal line of a semiconductor device in accordance with an embodiment of the present invention.

While the disclosed method is susceptible of embodiments in various forms, a specific embodiment is illustrated in the drawing (and will hereafter be described), with the understanding that the disclosure is not intended to limit the invention to the specific embodiment described and illustrated herein.

### DESCRIPTION OF SPECIFIC EMBODIMENT

Referring to FIG. 1A, a lower metal line 12 is formed on a semiconductor substrate 10 in which specific structures (not shown), such as gates, are formed. The lower metal line 12 can be an aluminum (Al) layer. In order to ensure etch margin in a subsequent contact process, a first insulating layer 14 can be formed on the lower metal line 12 using materials having etch selectivity different from that of the lower metal line 12. The first insulating layer 14 can be a silicon oxynitride (SiON) layer. Because aluminum (Al) of the lower metal line 12 does not react with the first insulating layer 14, formation of AlN, which hinders guarantee of resistance, can be prevented at the interface of the lower metal line 12 and the first insulating layer 14. Accordingly, contact resistance can be prevented from increasing.

A second insulating layer 16 can be formed on the first insulating layer 14. The second insulating layer 16 is used as a pre-metal dielectric layer. The second insulating layer 16 is formed from oxide-based materials, such as one selected from a group consisting of a high density plasma (HDP) oxide layer, spin on glass (SOG), boron-phosphorus silicate glass (BPSG), plasma-enhanced tetra ethyl ortho silicate (PE-TEOS), undoped silicate glass (USG), and phosphorus silicate glass (PSG).

Referring to FIG. 1B, the second insulating layer 16 and the first insulating layer 14 are etched using an etch process employing a mask (not shown). The etch has to be stopped on a top surface of the lower metal line 12 to prevent contact resistance from increasing. Accordingly, a contact hole 18 through which the surface of the lower metal line 12 is exposed is formed in the second insulating layer 16 and the first insulating layer 14.

Referring to FIG. 1C, a first barrier metal layer 20 is formed on a surface of the second insulating layer 16, including the contact hole 18. The first barrier metal layer 20 can have a stacked structure of a Ti layer 20a, a Ti-rich TiₓN layer 20b (wherein x is an integer greater than 1), and a TiN layer 20c, which have a liner form.

For example, the Ti layer 20a can be formed to a thickness of about 100 to about 300 angstroms. The Ti-rich TiₓN layer 20b is formed by purging N₂ gas for a specific time period in the last deposition step of the Ti layer 20a, and then flowing heated argon (Ar) gas into a chamber so that a temperature within the chamber and a temperature of the semiconductor substrate 10 are raised. Thus, a top surface of the Ti layer 20a is substituted with the Ti-rich TiₓN layer 20b through reaction.

If the top surface of the Ti layer 20a is substituted with the Ti-rich TiₓN layer 20b as described above, reaction of the Ti-rich TiₓN layer 20b and aluminum (Al), which is subsequently deposited to form a metal line, can be prohibited, thus preventing the formation of TiAl₃, which hinders in guaranteeing resistance. Further, an increase of contact resistance can be prevented or reduced.

The TiN layer 20c is formed by depositing TiN using a physical vapor deposition (PVD) method so that it has a low step coverage characteristic. The TiN layer 20c can be formed to a thickness of about 100 to about 200 angstroms on the Ti-rich TiₓN layer 20b. The TiN layer 20c is formed thinner at the bottom of the contact hole 18 than on the sidewalls and a top surface of the second insulating layer 16 due to the low step coverage characteristic. The TiN layer 20c is also formed thinner on the sidewalls of the second insulating layer 16 than on the top surface of the second insulating layer 16. Accordingly, the area occupied by the first barrier metal layer 20 within the contact hole 18 is decreased and therefore contact resistance can be reduced.

Deposition of the TiN layer 20c at the bottom of the contact hole 18 can be minimized. Thus, when depositing aluminum (Al) for forming a metal line using a CVD method employing methyl pyrrolidine alane (MPA, (CH₃)(CH₂)₄N.AlH₃)) source as a precursor, aluminum (Al) can be prevented from being formed in an island fashion. Accordingly, it improves the formation of the aluminum (Al) layer and, therefore, improves a gap-fill characteristic of the contact hole 18.

Referring to FIG. 1D, a first metal layer 22 is formed on the first barrier metal layer 20, including the contact hole 18, so that the contact hole 18 is gap-filled. The first metal layer 22 is formed from aluminum (Al) to lower resistance of a metal line formed in a subsequent process.

The first metal layer 22 is formed using a CVD method and can be formed using a CVD method employing MPA source as a precursor. If the CVD method using the MPA source is employed, the first metal layer 22 is grown sporadically in an island form on the TiN layer 20c through reaction of the MPA source and the surface of the TiN layer 20c. However, the first metal layer 22 is not formed in an island form within the contact hole 18 in which the thickness of the TiN layer 20c is thin and sporadically formed islands gather to become the aluminum (Al) layer. The first metal layer 22 can be formed to a thickness of about 500 to about 1000 angstroms.

Referring to FIG. 1E, thermal treatment for raising a temperature of the semiconductor substrate 10 to about 430 to about 450 degrees Celsius is performed by injecting heated argon (Ar) gas into a chamber. Thus, as the temperature of the semiconductor substrate 10 is raised by this thermal treatment, the sporadically formed islands on the TiN layer 20c of the first metal layer 22 gather and are smooth, and some of the islands are flown. Consequently, the inside of the contact hole 18 is stably gap-filled with the first metal layer 22, that is, the aluminum (Al) layer, thus forming a contact plug 22a.

When thermal treatment is performed after the first metal layer 22 is deposited using a CVD method employing the MPA source as a precursor, the inside of the contact hole 18 can be gap-filled efficiently and, therefore, the contact plug 22a can be formed stably.

Although a current damascene scheme using aluminum (Al) is used, a CMP process can be omitted. Accordingly, problems such as dishing and scratch that were generated upon CMP due to a relatively soft characteristic of aluminum (Al) can be avoided, and factors that degrade reliability of a subsequent metal line can be prevented.

Referring to FIG. 1F, a second metal layer 24 is formed on the contact plug 22a. The second metal layer 24 can be formed from aluminum (Al) by sequentially performing a cold deposition step, a pre-heat step, and a hot deposition step using a PVD method.

For example, in the cold deposition step, an aluminum (Al) layer can be formed to a thickness of about 2000 to about 3000 angstroms. A temperature of the chamber and the semiconductor substrate 10 is raised through the pre-heat step using heated argon (Ar). In the hot deposition step, the aluminum (Al) layer increases to a thickness of about 2000 to about 5000 angstroms.

A second barrier metal layer 26 is formed on the second metal layer 24. The second barrier metal layer 26 can have a stacked layer of Ti/TiN. The second barrier metal layer 26 can be formed in-situ after depositing the second metal layer 24.

Referring to FIG. 1G, the second barrier metal layer 26 and the second metal layer 24 are patterned using an etch process employing a mask (not shown). Accordingly, an upper metal line 24a comprised of the second metal layer 24 is formed. The upper metal line 24a becomes a low resistance due to reduced contact resistance.

As described above, in the present embodiment, resistive capacitive (RC) delay is reduced through the formation of the upper metal line 24a with a low resistance. Accordingly, a program speed of a semiconductor device can be increased and consumption power can be reduced.

The disclosed method provides a number of advantages. First, the TiN layer is formed using a PVD method so that it has a low step coverage characteristic to minimize deposition of the TiN layer at the bottom of the contact hole. Thus, when subsequently depositing the aluminum (Al) layer for forming a metal line, aluminum (Al) can be prevented from being formed in island form. Accordingly, it improves the formation of the aluminum (Al) layer and, therefore, can improve a gap-fill characteristic of the contact hole.

Second, the area occupied by the barrier metal layer within the contact hole is decreased by minimizing deposition of the TiN layer at the bottom of the contact hole. Accordingly, contact resistance can be reduced.

Third, a top surface of the Ti layer is substituted with the Ti-rich TiₓN layer (wherein x is an integer greater than 1) to minimize reaction of aluminum, which gap-fills the contact hole, and the first barrier metal layer. Accordingly, formation of material (TiAl₃), hindering in ensuring resistance, can be prohibited and, therefore, contact resistance can be reduced.

Fourth, the insulating layer is formed on the lower metal line using material having etch selectivity different from that of the lower metal line. Accordingly, etch margin can be secured when the contact hole is formed and contact resistance can be reduced.

Fifth, material having etch selectivity different from that of the lower metal line includes material that does not react with the lower metal line. Accordingly, formation of material, which hinders in securing resistance at the interface, can be prohibited and, therefore, an increase of contact resistance can be prohibited.

Sixth, because contact resistance is reduced and a gap-fill characteristic is improved, RC delay can be reduced though formation of a low-k metal line. Accordingly, the program speed of a semiconductor device can be increased and low consumption power can be realized.

Seventh, after performing a CVD method employing MPA source, the inside of the contact hole is gap-filled with the aluminum layer through a reflow process. Accordingly, a CMP process for polishing the aluminum (Al) layer can be omitted and, therefore, factors that degrade reliability of a metal line can be prohibited.

An embodiment of the invention has been described for illustrative purposes. Therefore, the scope of the invention is not limited by or to the embodiment as described above, and should be construed to be defined only by the appended claims and their equivalents.

What is claimed is:

1. A method of forming a metal line of a semiconductor device, the method comprising:
forming a contact hole in a second insulating layer over a semiconductor substrate;
forming a first barrier metal layer, comprising a TiN layer, on a surface of the second insulating layer, such that the TiN layer is formed thinner at a bottom of the contact hole than on sidewalls and a top surface of the second insulating layer;
forming a first metal layer on the first barrier metal layer, including on the contact hole;
performing a thermal treatment to gap-fill the contact hole as the first metal layer is reflown and smooth;
forming a second metal layer on the first metal layer; and,
pattering the second metal layer to form an upper metal line.

2. The method of claim 1 comprising forming the TiN layer by a physical vapor deposition (PVD) method.

3. The method of claim 1, wherein the TiN layer has a thickness of about 100 to about 200 angstroms.

4. The method of claim 1, wherein the first barrier metal layer comprises a stacked structure of a Ti layer, a Ti-rich TiₓN layer, and the TiN layer, wherein x is an integer greater than 1.

5. The method of claim 4, wherein the Ti layer has a thickness of about 100 to about 300 angstroms.

6. The method of claim 4 comprising forming the Ti-rich TiₓN layer by purging N₂ gas in a last deposition step of the Ti layer and flowing heated Ar gas into a chamber such that a temperature within the chamber and a temperature of the semiconductor substrate are raised, and a top surface of the Ti layer is substituted with the Ti-rich TiₓN layer through reaction.

7. The method of claim 1, wherein the first metal layer and the second metal layer each comprises aluminum (Al).

8. The method of claim 7 comprising forming the first metal layer by a chemical vapor deposition (CVD) method employing Methyl Pyrrolidine Alane (MPA, (CH₃)(CH₂)₄N.AlH₃)) source as a precursor.

9. The method of claim 1, wherein the first metal layer has a thickness of about 500 to about 1000 angstroms.

10. The method of claim 1, wherein the thermal treatment comprises raising a temperature of the semiconductor substrate to about 430 to about 450 degrees Celsius.

11. The method of claim 7 comprising forming the second metal layer by a PVD method.

12. The method of claim 11, wherein the PVD method comprises performing a cold deposition step, a pre-heat step, and a hot deposition step.

13. The method of claim 12, wherein an aluminum (Al) layer having a thickness of about 2000 to about 3000 angstroms, the pre-heat step comprises raising a temperature of a chamber and the semiconductor substrate and the hot deposition step comprises increasing the thickness of the aluminum layer to about 2000 to about 5000 angstroms.

14. The method of claim 1 further comprising forming a lower metal line and a first insulating layer over the semiconductor substrate before the second insulating layer is formed.

15. The method of claim 14, wherein the lower metal line comprises aluminum (Al).

16. The method of claim 14, wherein the first insulating layer comprises materials having etch selectivity different from that of the lower metal line.

17. The method of claim 16, wherein the first insulating layer comprises a silicon oxynitride (SiON) layer.

18. The method of claim 14 further comprising stopping the etch on a top surface of the lower metal line when the contact hole is formed.

19. The method of claim 1 further comprising forming a second barrier metal layer on the upper metal line.

20. The method of claim 19, wherein the second barrier metal layer has a stacked layer of Ti and TiN.
